(19) United States
(12) Patent Application Publication
(10) Pub. No.: US 2025/0204108 A1
(43) Pub. Date: Jun. 19, 2025

(54) Display Apparatus

(71) Applicant: LG Display Co. Ltd., Seoul (KR)

(72) Inventors: Mira Yun, Goyang-si (KR); Changho Lee, Paju-si (KR)

(21) Appl. No.: 18/919,025

(22) Filed: Oct. 17, 2024

(30) Foreign Application Priority Data
Dec. 15, 2023 (KR) 10-2023-0183160

(51) Int. Cl. H01L 33/58; H01L 25/075

(52) U.S. Cl. CPC H10H 20/855; H01L 25/0753

(57) ABSTRACT

A display apparatus may include a panel, a light source unit provided on the panel and for displaying an image, and an image conversion unit disposed in front of the light source unit and for converting the image displayed from the light source unit into a two-dimensional image or a three-dimensional image, in which the light source unit may have a light emitting group in which a plurality of light emitting pixels are provided to be disposed to be spaced apart from each other on the panel, and a plurality of light emitting groups may be provided to be disposed to be spaced apart from each other on the panel.

### CROSS REFERENCE TO RELATED APPLICATION

The present application claims priority to Republic of Korea Patent Application No. 10-2023-0183160, filed on Dec. 15, 2023, which is hereby incorporated by reference in its entirety.

### BACKGROUND

### Field of Technology

The present disclosure relates to a display apparatus, and more specifically, to a display apparatus that implements a three-dimensional image having a structure with an increased resolution by suppressing optical crosstalk.

### Description of the Related Art

In the full-fledged information age, the field of display apparatuses for visually displaying electrical information signals is developing rapidly, and research for developing performance, such as thinness, lightweight, and lower power consumption, for various display apparatuses is being continuously conducted.

Such display apparatuses include a liquid crystal display (LCD) device, a quantum dot display panel device (QD), a field emission display (FED) device, and an electro-wetting display (EWD) device, an organic light emitting diode (OLED) display apparatus, etc.

The display apparatuses have been developed to be miniaturized so that users may carry the display apparatuses or to be mounted on movable devices such as vehicles, etc., and are being improved so that the users may use the display apparatuses more conveniently.

In addition, the display apparatus is continuously improved to provide a clear image to a user by increasing a resolution and luminance of a screen.

### SUMMARY

A display apparatus may be provided to provide a three-dimensional image to a user. A display apparatus may display different images on the user's left and right eyes viewing the screen to allow the user to view a three-dimensional image without wearing glasses that implement the three-dimensional image.

When the three-dimensional image is implemented, light having images radiated to the user's left and right eyes is different, and optical crosstalk may occur in which some light overlap each other due to similar optical paths of the light having the images.

When the light overlaps each other, the light causes complementary interference and destructive interference, thereby reducing the resolution of the image and distorting the image.

In addition, when the three-dimensional image is implemented, the path of the light having the same image is separated and the light is sent to each of the user's left and right eyes, and since some light is blocked when the path of the light is separated, the luminance of the image visible to the user may be reduced.

In particular, in typical display apparatuses, such as an LCD, a plurality of pixels that display an image are consecutively disposed to radiate the light having the image to the user.

In this case, when some light is blocked to separate the path of the light, the luminance of the image may be reduced, thereby reducing the resolution of the image.

In addition, in this case, crosstalk may increase when some light is blocked from the plurality of pixels consecutively disposed without a separated space.

There is a need to develop a display apparatus that implements a three-dimensional image that improves the problems.

The present disclosure is directed to providing a display apparatus that implements a three-dimensional image having a structure with an increased resolution by suppressing optical crosstalk.

The present disclosure is also directed to providing a display apparatus that implements a three-dimensional image, which increases a resolution by increasing the luminance of an image to be displayed.

Objects of the present disclosure are not limited to the above-described objects, and other objects and advantages of the present disclosure which are not mentioned can be understood by the following description and more clearly understood by embodiments of the present disclosure. In addition, it will be able to be easily seen that the objects and advantages of the present disclosure may be achieved by devices and combinations thereof that are described in the claims.

One embodiment of a display apparatus may include a light source unit configured to display an image, and an image conversion unit disposed in front of the light source unit and configured to convert an image displayed from the light source unit into a two-dimensional image or a three-dimensional image.

The light source unit may have a light emitting group in which a plurality of light emitting pixels are disposed to be spaced apart from each other on the panel, and a plurality of light emitting groups may be provided to be disposed to be spaced apart from each other on the panel.

A separation distance between the plurality of light emitting group may be provided to be greater than a separation distance between the plurality of pixels.

The pixel may be provided as a micro-LED.

The image conversion unit may be provided as any one of a lens unit in which a refractive index of light is adjusted according to a control signal and a barrier covering some of the plurality of pixels according to the control signal.

The lens unit may include a body, and a convex lens protruding from the body, provided as a plurality of lens, and arranged in the first direction, and at least some of the convex lenses may be provided to have the same width in a longitudinal direction.

The barrier may include a support disposed in front of the light source unit and made of a transparent material, and a blocking film disposed in front of the support and changed to be transparent or opaque according to the control signal, and a plurality of blocking films may be provided to be arranged to be spaced apart from each other in the first direction.

Another embodiment of a display apparatus may include a light source unit configured to display an image, and an image conversion unit disposed in front of the light source unit and configured to convert an image displayed from the light source unit into a two-dimensional image or a three-dimensional image.

The image conversion unit may be provided as any one of a lens unit in which a refractive index of light is adjusted according to a control signal and a barrier covering some of the plurality of pixels according to the control signal, the light source unit may have a light emitting group in which a plurality of light emitting pixels are disposed to be spaced apart from each other on the panel, and a plurality of light emitting groups may be provided to be disposed to be spaced apart from each other on the panel.

### BRIEF DESCRIPTION OF THE DRAWINGS

FIG. 1 is a perspective view showing a display apparatus according to one embodiment.

FIG. 2 is a plan view showing the display apparatus according to one embodiment.

FIG. 3 is a side view showing the display apparatus according to one embodiment.

FIG. 4 is a front view showing the display apparatus according to one embodiment.

FIG. 5 is an enlarged view of portion A in FIG. 4 according to one embodiment.

FIG. 6 is a perspective view showing a display apparatus having a lens unit of FIG. 1 according to another embodiment.

FIG. 7 is a perspective view showing a display apparatus having an image conversion unit of FIG. 1 according to another embodiment.

FIG. 8 is a plan view of FIG. 7 according to one embodiment.

FIG. 9 is a view showing a state in which a blocking film in FIG. 8 has become opaque according to one embodiment.

FIG. 10 is a plan view of FIG. 7 according to one embodiment.

FIG. 11 is a perspective view showing a display apparatus having a blocking film of FIG. 7 according to another embodiment.

FIG. 12 is a front view showing a display apparatus having a lens unit of FIG. 1 according to another embodiment.

FIG. 13 is a front view showing a display apparatus having an image conversion unit of FIG. 12 according to another embodiment. FIG. 13 shows a state in which the blocking film has become opaque.

### DETAILED DESCRIPTION

The above-described objects, features, and advantages will be described below in detail with reference to the accompanying drawings, and thus those skilled in the art to which the present disclosure pertains will be able to easily carry out the technical spirit of the present disclosure. In describing the present disclosure, when it is determined that a detailed description of the known technology related to the present disclosure may unnecessarily obscure the gist of the present disclosure, a detailed description thereof will be omitted. Hereinafter, exemplary embodiments according to the present disclosure will be described in detail with reference to the accompanying drawings. In the drawings, the same reference numerals are used to denote the same or similar components.

Although terms such as first and second are used to describe various components, it goes without saying that the components are not limited by these terms. These terms are only used to distinguish one component from another component, and unless otherwise stated, it goes without saying that the first component may be the second component.

Throughout the specification, unless otherwise stated, each component may be singular or plural.

The singular expression used herein includes the plural expression unless the context clearly dictates otherwise. In the application, terms such as “composed of” or “comprising” should not be construed as necessarily including all of the various components or operations described in the specification and should be construed as not including some of the components or some of the operations or further including additional components or operations.

Throughout the specification, when “A and/or B” is described, this means A, B, or A and B unless otherwise specified, and when “C to D” is described, this means C or more and D or less unless otherwise specified.

In the following description, when the user views the display apparatus in a state in which the display apparatus is disposed to be generally used, a direction in which the user is located is referred to as “forward,” and a direction opposite to the front is referred to as “backward.”

In addition, “vertically,” “upper side,” “lower side,” “above,” “under” indicates a location or direction of each component in a state in which the display apparatus is disposed to be generally used. In the drawing, “forward” indicates a +X-axis direction, “backward” indicates a-X-axis direction, and “vertically” indicates a Z-axis direction. In addition, “lateral direction,” “left-right direction,” and “both directions” indicate a Y-axis direction in the drawings.

Meanwhile, for clear description, the terms “first direction” and “second direction” may be used in the specification, and the first direction indicates the Y-axis direction, and the second direction indicates a Z-axis direction orthogonal to the first direction.

The display apparatus according to the embodiment is a display apparatus for allowing a user to view a three-dimensional image without using so-called three-dimensional glasses for allowing the user to view the three-dimensional image.

The display apparatus may provide both two-dimensional images and three-dimensional images to the user under the control of a controller provided therein. The controller may control the display apparatus to change a viewing mode of the display apparatus between the two-dimensional image and the three-dimensional image.

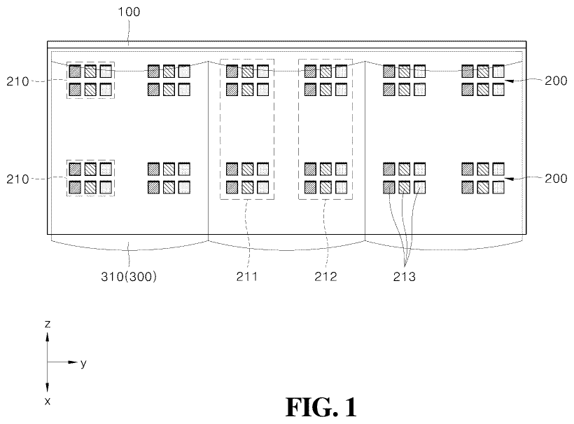

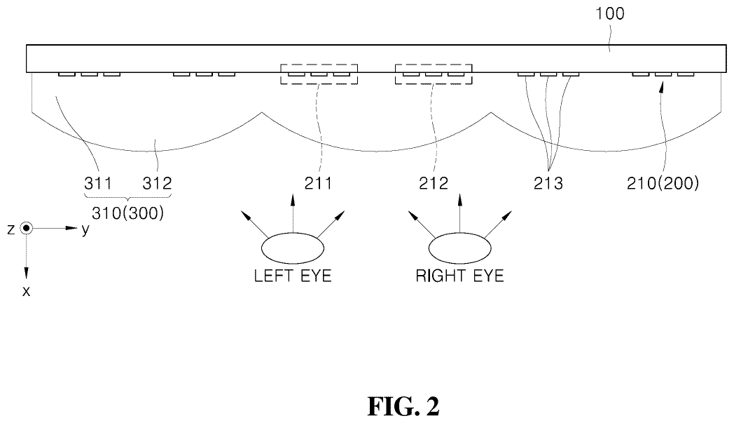

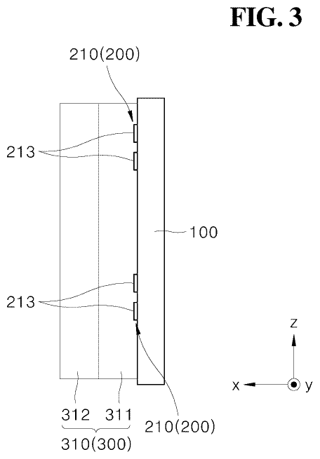

FIG. 1 is a perspective view showing a display apparatus according to one embodiment. FIG. 2 is a plan view showing the display apparatus according to one embodiment. FIG. 3 is a side view showing the display apparatus according to one embodiment.

The display apparatus according to one embodiment may include a panel 100, a light source unit 200, and an image conversion unit 300.

The light source unit 200 may be disposed on the panel 100. The panel 100 may be formed in a plate shape, and the light source unit 200 may be formed on a front surface of the panel 100. The panel 100 forms a rear appearance of the display apparatus, and various elements and circuits for supplying electricity to the light source unit 200 may be provided therein.

The light source unit 200 may be provided on the panel 100 to display a video or image. The light source unit 200 may include a pixel 213 that displays the video or image. The light source unit 200 will be described in detail below.

The image conversion unit 300 may be disposed in front of the light source unit 200 to convert the image displayed from the light source unit 200 into a two-dimensional image or a three-dimensional image.

Light emitted from the light source unit 200 may pass through the image conversion unit 300. In this case, the image conversion unit 300 may operate to separate a path of light to generate the three-dimensional image or integrate the paths of light to generate the two-dimensional image.

The image conversion unit 300 may be provided as any one of a lens unit 310 in which a refractive index of light is adjusted according to a control signal received from the controller or a barrier 320 that blocks some of the plurality of pixels 213 according to the control signal.

In the embodiment shown in FIGS. 1 to 3, the image conversion unit 300 may be provided as the lens unit 310. Hereinafter, first, the display apparatus in which the image conversion unit 300 is provided as the lens unit 310 will be described.

The lens unit 310 may be made of a transparent material and may include a body 311 and a convex lens 312.

The body 311 may be disposed in front of the light source unit 200 and filled with a material that changes the path of light emitted from the light source unit 200 by moving in response to commands from the controller provided in the display apparatus. Such a light path change material may be, for example, liquid crystal.

The convex lens 312 protrudes from the body 311 and may be provided as a plurality of convex lenses and arranged in a first direction, that is, in a Y-axis direction in the drawing. The inside of the convex lens 312 may also be filled with a material that changes the path of light.

The panel 100 may be provided with a device or element for controlling the movement of the light path change material filled in the lens unit 310 according to the signal transmitted from the controller.

At least some of the convex lens 312 may be provided to have the same width in a longitudinal direction. The convex lens 312 may be provided to have the same width in a second direction orthogonal to the first direction, that is, a Z-axis direction in the drawing.

The convex lens 312 may be disposed to have a longitudinal direction orthogonal to the first direction. The convex lens 312 may be disposed to have a longitudinal direction parallel to the second direction orthogonal to the first direction.

Due to the structure of the convex lens 312, separate images may be incident on the user's left and right eyes, which are spaced apart in the first direction, and the user may view the image displayed on the display apparatus in a three dimension.

The controller of the display apparatus may transmit a signal for displaying the three-dimensional image to the panel 100. Therefore, the path of light emitted from the light source unit 200 may be changed by moving the light path change material filled in the lens unit 310, and thus the light may be separated and incident on each of the user's left and right eyes, and the user may view the three-dimensional image.

When the controller transmits the signal for re-displaying a two-dimensional shape to the panel 100, the light path change material inside the lens unit 310 may be re-moved to an original location, and thus the image displayed from the light source unit 200 may be incident on the user's eyes as the two-dimensional image, and the user may view the two-dimensional image.

Such a signal may be implemented by applying electricity to the lens unit 310 to generate an electric field in the liquid crystal filled in the lens unit 310.

The lens unit 310 may be filled with liquid crystal, which is the light path change material. Since the liquid crystal may be moved by the electric field, a refractive index thereof may be changed. The liquid crystal may be controlled to turn on/off the three-dimensional image by the electric field. That is, the lens unit 310 may be manufactured by being filled with the liquid crystal that allows the three-dimensional image to be turned on/off by the electric field.

An electrode that supplies electricity from the outside may be connected to the lens unit 310. For example, the controller may be connected to the electrode, and the electrode may receive electricity through the controller.

The controller may apply the electric field to the lens unit 310 through the electrode and thus change the path of the light passing through the lens unit 310 by finely controlling the refractive index of the liquid crystal filled in the lens unit 310, and as a result, convert the light into the three-dimensional image or the two-dimensional image.

The light source unit 200 may include a light emitting group 210 in which a plurality of light emitting pixels 213 are disposed to be spaced apart from each other on the panel 100. One light emitting group 210 may be provided with the plurality of pixels 213.

The plurality of pixels 213 in the light emitting group 210 may display an image in combination of red, blue, and green (RGB). The pixels 213 in one light emitting group 210 may be disposed to be spaced apart from each other.

That is, the light emitting group 210 may be provided so that the plurality of pixels 213 are disposed to be spaced apart from each other on the panel 100 in a plan view. In the same light emitting group 210, each of the plurality of pixels 213 may be disposed to be spaced apart from each other in the first direction and disposed to be spaced apart from each other in the second direction orthogonal to the first direction.

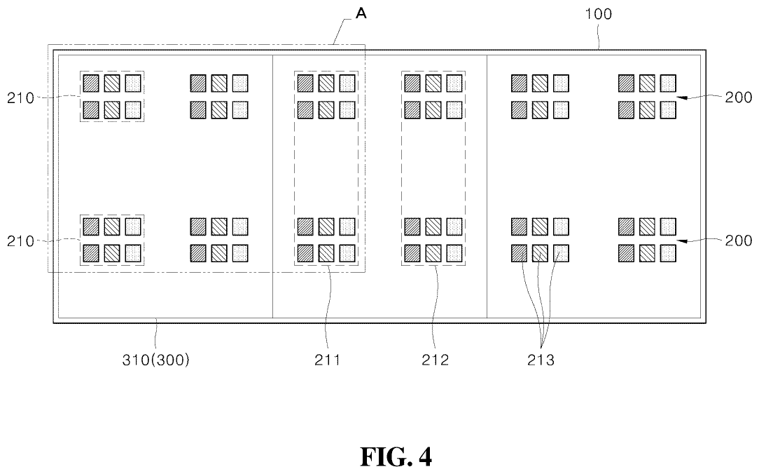

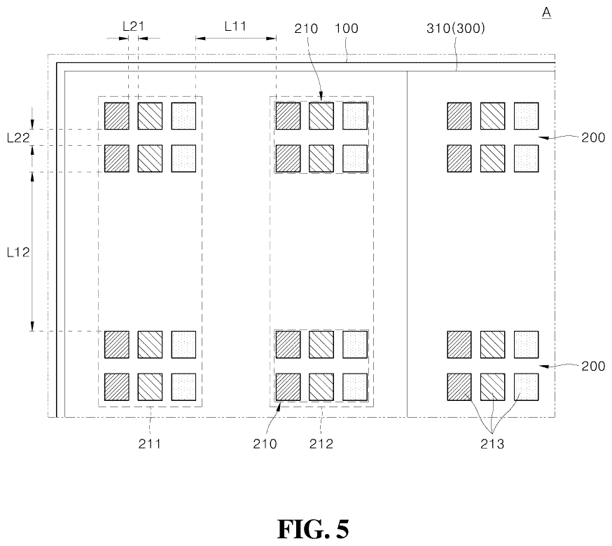

FIG. 4 is a front view showing the display apparatus according to one embodiment. FIG. 5 is an enlarged view of portion A in FIG. 4 according to one embodiment. A plurality of light emitting groups 210 may be provided to be disposed to be spaced apart from each other on the panel 100.

The plurality of light emitting groups 210 may be disposed to be spaced apart from each other in the first direction and disposed to be spaced apart from each other in the second direction orthogonal to the first direction. Therefore, the plurality of light emitting groups 210 may be disposed to be spaced apart from each other on the panel 100 in a plan view.

In any one light emitting group 210, some of the plurality of pixels 213 may display an image viewed by the user's left eye, and the remaining pixels 213 of the plurality of pixels 213 may display an image viewed by the user's right eye.

The left-eye image and the right-eye image may be displayed on the display apparatus, and as the images pass through the image conversion unit 300, the path of light may be adjusted so that the user may view the three-dimensional image.

The user may view the three-dimensional image only when the left and right images are not mixed and are separated. When the left and right images are not accurately separated, the three-dimensional effect and image quality of the three-dimensional image may be degraded. Therefore, the image conversion unit 300 may serve to separate the left and right images.

In an embodiment, the light passing through the image conversion unit 300 may be separated, and thus the path of light may be adjusted so that the left-eye image enters only the left eye and the right-eye image enters only the right eye to allow the user to view the three-dimensional image.

When the image conversion unit 300 operates to display the three-dimensional image, the light emitted from pixels 213 included in the same light emission group 210 may be separated. Therefore, some of the separated light may enter the user's left eye and the remainder of the separated light may enter the user's right eye to allow the user to view the three-dimensional image.

Separation distances L11 and L12 between the plurality of light emitting groups 210 may be provided to be greater than separation distances L21 and L22 between the plurality of pixels 213.

Referring to FIG. 5, in the separation distances L11 and L12 between the light emitting groups 210, the separation distance in the first direction is L11 and the separation distance in the second direction is L12. In the separation distances L21 and L22 between the pixels 213, the separation distance in the first direction is L21, and the separation distance in the second direction is L22.

In this case, L11 and L12 may be provided to be the same, L11 may be provided to be greater than L12, or L12 may be provided to be greater than L11. In addition, L21 and L22 may be provided to be the same, L21 may be provided to be greater than L22, or L22 may be provided to be greater than L21.

Meanwhile, L11 and L12 are appropriately provided to be greater than L21 and L22. That is, the separation distances L21 and L22 between the pixels 213 in the same light emitting group 210 may be provided to be smaller than the separation distances L11 and L12 between different light emitting groups 210.

Since similar and continuous images are displayed in the same light emitting group 210, image distortion due to crosstalk is relatively small, but since different images are displayed in different light emitting groups 210, image distortion due to crosstalk is relatively large.

Therefore, in the embodiment, by separating the different light emitting groups 210 having large image distortion due to crosstalk to be relatively far away from each other, it is possible to reduce the crosstalk occurring when images overlap each other due to the small distance between different images displayed between different light emitting groups 210 when the three-dimensional image is displayed.

Meanwhile, as described above, the display apparatus may separately display the left-eye image and the right-eye image in the same light emitting group 210, but in another embodiment, may separately display each of the left-eye image and the right-eye image in different light emitting groups 210.

The left-eye image and the right-eye image become the three-dimensional images while passing through the image conversion unit 300 so that the user may view the three-dimensional image. Hereinafter, a structure in which the left-eye image and the right-eye image may each be separately displayed in different light emitting groups 210 will be described.

The light source unit 200 may include a first array 211 and a second array 212. The first array 211 may have a plurality of light emitting groups 210 arranged linearly. For example, the first array 211 may be provided in a structure in which the plurality of light emitting groups 210 are disposed to be spaced apart from each other in the second direction.

The second array 212 may be disposed to be spaced apart from the first array 211, and the plurality of light emitting groups 210 may be arranged linearly. For example, the second array 212 may be provided in a structure in which the plurality of light emitting groups 210 are disposed to be spaced apart from each other in the second direction.

The first array 211 and the second array 212 may be disposed adjacent to each other. The light source unit 200 may be provided in a structure in which the plurality of first arrays 211 and second arrays 212 are alternately disposed in the first direction on the panel 100.

In this case, any one of the first array 211 and the second array 212 may display an image viewed by the user's left eye, and the other may display an image viewed by the user's right eye.

The left-eye image and the right-eye image may be converted into the three-dimensional image while passing through the lens unit 310 or the barrier 320, which will be described below, so that the user may view the three-dimensional image.

In an embodiment, the light source unit 200 for displaying the image may be provided as the plurality of light emitting groups 210 disposed to be spaced apart from each other. The light emitting group 210 may include the plurality of pixels 213.

Since the light emitting groups 210 spaced apart from each other display different images and are quite away from each other, compared to other display apparatuses in which a plurality of pixels 213 are consecutively disposed to display an image, it is possible to significantly reduce the occurrence of crosstalk between separated light groups 210 displaying different images. Therefore, it is possible to increase the resolution of the three-dimensional image.

In addition, the pixel 213 may be provided as a micro-LED. The micro-LED has very high luminance per unit area compared to other light emitting devices such as an LCD.

Therefore, as described above, in the display apparatus according to the embodiment, the light emitting groups 210 may be disposed to be spaced apart from each other at a considerable distance. In this case, it is possible to reduce the luminance of a light emitting portion of the display apparatus, thereby reducing the resolution.

In an embodiment, it is possible to greatly increase the luminance of the display apparatus by manufacturing the pixels 213 forming the light emitting group 210 of the light source unit 200 as the micro-LED. Therefore, even when the light emitting groups 210 are consecutively disposed on the panel 100 without separation distance, the light source unit 200 may have sufficient luminance.

In addition, when the light source conversion unit operates, the light source conversion unit may cover some images or reduce the luminance of the image, and an image having sufficient luminance may be displayed by forming the light source unit as the micro-LED. Therefore, it is possible to increase the resolution of the image to be displayed by increasing the luminance of the image.

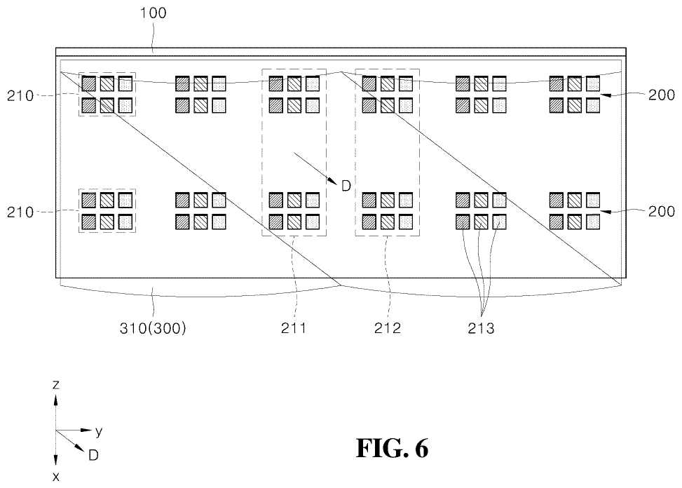

FIG. 6 is a perspective view showing a display apparatus having the lens unit 310 according to another embodiment of FIG. 1. At least some of the convex lenses 312 of the lens unit 310 according to another embodiment may be disposed to have a longitudinal direction inclined with respect to the first direction.

In FIG. 6, the first direction indicates the Y-axis direction, and the longitudinal direction of the convex lens 312 is shown as a D direction.

When the user views the displayed screen, the user's left and right eyes may be placed in a direction parallel to the first direction. Therefore, when the longitudinal direction of the convex lens 312 is disposed in the second direction orthogonal to the first direction, the light radiated from the light source unit 200 may be refracted on the surface of the convex lens 312, making it difficult to spread in the first direction.

Therefore, the angle of view of the image output from the display apparatus may be reduced. To solve such a problem, at least some of the plurality of convex lenses 312 may be disposed to have their longitudinal directions inclined with respect to the first direction.

With this structure, it is possible to increase the angle of view of the display apparatus. That is, it is possible to increase the angle of view of the display apparatus by arranging the longitudinal direction of the convex lens 312 in a direction somewhat similar to the arrangement direction of the user's left and right eyes.

Therefore, due to the increased angle of view, more people may view high-resolution images on one display apparatus.

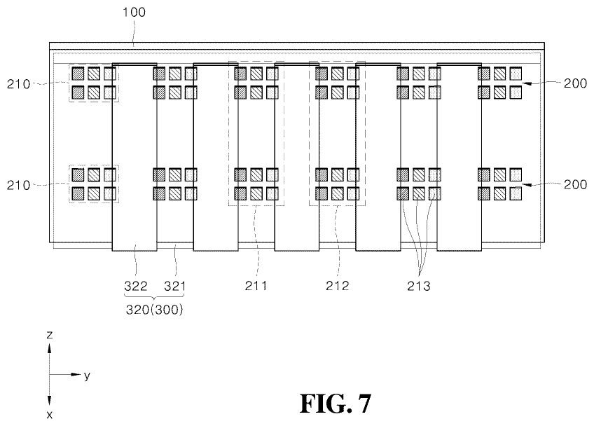

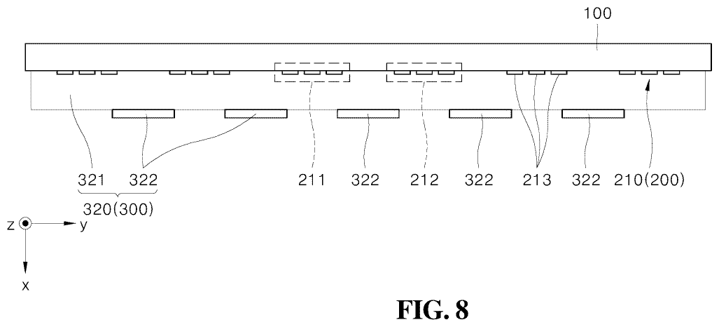

FIG. 7 is a perspective view showing a display apparatus having a lens unit 300 according to another embodiment of FIG. 1. FIG. 8 is a plan view of FIG. 7 according to one embodiment.

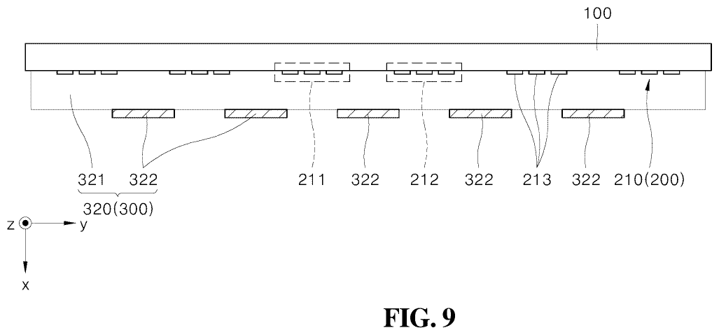

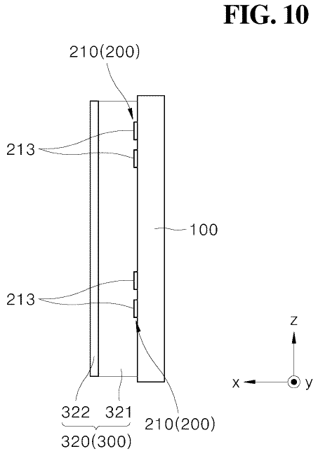

FIG. 9 is a view showing a state in which a blocking film 322 in FIG. 8 has become opaque according to one embodiment. FIG. 10 is a plan view of FIG. 7 according to one embodiment.

The image conversion unit 300 may be provided as the barrier 320. The barrier 320 may include a support 321 and the blocking film 322. The support 321 may be disposed in front of the light source unit 200 and made of a transparent material. Therefore, the light radiated from the light source unit 200 may pass through the support 321 without obstruction.

The blocking film 322 may be disposed in front of the support 321 and changed to be transparent or opaque according to the control signal. The blocking film 322 may be attached to a front surface of the support 321 and provided to protrude from the front surface.

In another embodiment, a groove for accommodating the blocking film 322 may be formed in the support 321, and the blocking film 322 may be inserted into the groove and attached to the support 321 to make the front surface of the display apparatus generally flat.

A plurality of blocking films 322 may be provided to be arranged to be spaced apart from each other in the first direction. Therefore, when the blocking film 322 operates and becomes opaque, some images may be displayed.

In one embodiment, the blocking film 322 may be disposed to have a longitudinal direction parallel to the second direction orthogonal to the first direction. However, the arrangement structure of the blocking film 322 according to another embodiment will be described below.

The blocking film 322 may be provided, for example, in a structure that becomes opaque due to discoloring occurring when electricity is applied. The controller of the display apparatus may be electrically connected to the blocking film 322 and may apply electricity to the blocking film 322 to be discolored when the blocking film 322 operates.

The blocking film 322 may be connected to an electrode that receives the electricity. The electrode may be connected to the controller to receive the electricity from the controller. The controller may control the blocking film 322 to be turned on and off to allow the blocking film to be opaque or transparent by applying the electricity to the blocking film 322 to generate the electric field in the blocking film 322.

The blocking film 322 may be filled with a material in which the path of light is changed when an electric field is applied, such as liquid crystal. In addition, a polarizer may be provided on at least one of upper and lower surfaces of the blocking film 322.

Therefore, when the electric field is applied to the blocking film 322 to change the path of light and the light is polarized by the polarizer, the light may not pass through the blocking film 322 and may be blocked, and thus the blocking film 322 may be discolored to become opaque. Therefore, the blocking film 322 may be controlled to be turned on and off to be opaque or transparent through the electric field.

Since the operation of the light source unit 200 is the same as that of the display apparatus including the lens unit 310, only the operation of the barrier 320 will be described below.

A case where the display apparatus displays the two-dimensional image is as shown in FIG. 8. When the display apparatus displays the two-dimensional image, electricity is not applied to the blocking film 322, and thus the blocking film 322 is in a transparent state.

Therefore, all light radiated from the light source unit 200 may pass through the barrier 320 without any obstruction, and the user may view the two-dimensional image.

A case where the display apparatus displays the three-dimensional image is as shown in FIG. 9. When the display apparatus displays the three-dimensional image, electricity is applied to the blocking film 322, and thus the blocking film 322 may be discolored to be opaque.

Due to the blocking film 322, only some images may pass through the barrier 320, and in this process, the path of light of the image may be separated to implement the three-dimensional image. Therefore, the user may view the three-dimensional image implemented by the light passing through the barrier 320.

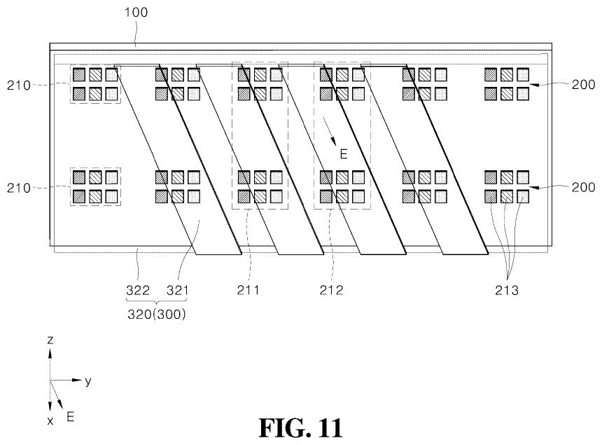

FIG. 11 is a perspective view showing a display apparatus having the lens unit 322 according to another embodiment of FIG. 7. The blocking film 322 of the barrier 320 according to another embodiment may be disposed to have a longitudinal direction inclined with respect to the first direction.

In FIG. 11, the first direction indicates the Y-axis direction, and the longitudinal direction of the blocking film 322 is shown as a E direction. Such a structure is similar to the structure shown in FIG. 6 and may increase the angle of view of the display apparatus.

When the user views the displayed screen, the user's left and right eyes may be placed in a direction parallel to the first direction. Therefore, when the longitudinal direction of the blocking film 322 is disposed in the second direction orthogonal to the first direction, the light radiated from the light source unit 200 may be refracted on the surface of the blocking film 322, making it difficult to spread in the first direction.

Therefore, the angle of view of the image output from the display apparatus may be reduced. To solve such a problem, the plurality of blocking films 322 may be disposed to have their longitudinal directions inclined with respect to the first direction.

With this structure, it is possible to increase the angle of view of the display apparatus. That is, it is possible to increase the angle of view of the display apparatus by arranging the longitudinal direction of the blocking film 322 in a direction somewhat similar to the arrangement direction of the user's left and right eyes.

Therefore, due to the increased angle of view, more people may view high-resolution images on one display apparatus.

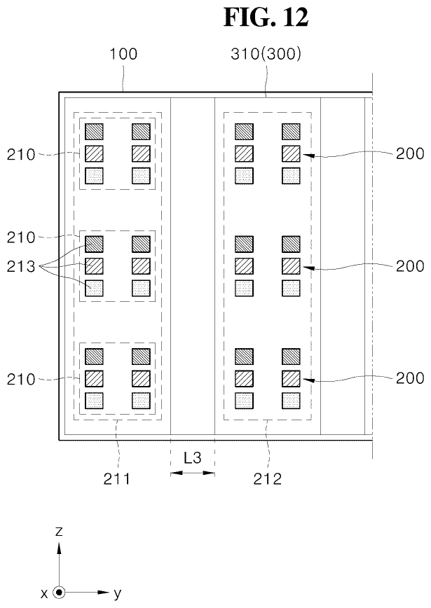

FIG. 12 is a perspective view showing a display apparatus having the lens unit 310 according to still another embodiment of FIG. 1. The convex lenses 312 of the lens unit 310 may be disposed to be spaced apart from each other in the first direction as shown in FIG. 12.

That is, in the lens unit 310, a separation distance L3 may be formed between the convex lenses 312 adjacent to each other. In the case of such a structure, it is possible to somewhat reduce the rate at which the light radiated from the light source unit 200 is refracted on a rounded surface of the convex lens 312.

Therefore, by somewhat reducing the change in path of light on the surface of the lens unit 310, it is possible to reduce image distortion due to the change in path of light and increase the resolution of the displayed image.

Meanwhile, unlike the above-described embodiment, in the embodiment shown in FIG. 12, more light emitting groups 210 may be disposed in the second direction. For example, in the embodiment shown before FIG. 11, two light emitting groups 210 are disposed in the second direction, but in the embodiment shown in FIG. 12, three light emitting groups 210 may be disposed in the second direction.

For example, it may be manufactured by rotating the panel 100 provided with the light source unit 200 shown in FIG. 1 at 90° and separating a part of the panel 100 from the entire panel 100.

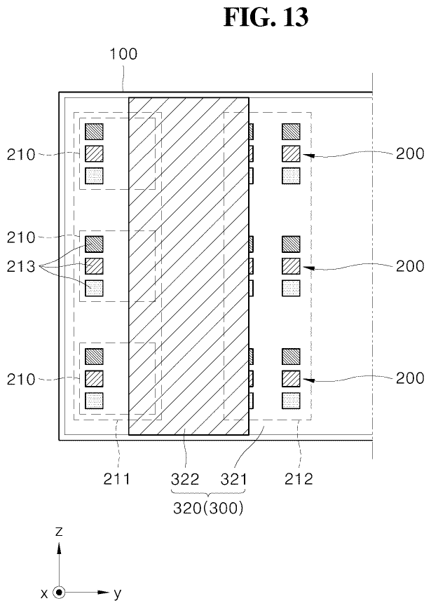

Such a structure can increase the luminance of light in the second direction in the display apparatus. Such a structure may be especially effective in a structure in which the barrier 320 is provided. The above will be described with reference to FIG. 13.

FIG. 13 is a front view showing a display apparatus having the image conversion unit 300 according to another embodiment of FIG. 12. FIG. 13 shows a state in which the blocking film 322 has become opaque.

In FIG. 13, the barrier 320 may be provided, and three light emitting groups 210 may be disposed in the second direction. In this case, the first array 211 and the second array 212, which have three light emitting groups 210 in the second direction, may be disposed to be spaced apart from each other in the first direction.

In addition, the blocking film 322 of the barrier 320 may be disposed to have a longitudinal direction parallel to the longitudinal directions of the first array 211 and the second array 212. In this case, the number of pixels 213 disposed between the plurality of blocking films 322 disposed to be spaced apart from each other in the first direction even when the blocking film 322 is discolored to be opaque may be larger than that of a case of having two light emitting groups 210 in the second direction.

Therefore, even when the three-dimensional image is displayed and the blocking film 322 is opaque, sufficient pixels 213 may be present between the plurality of blocking films 322, thereby increasing the luminance of the display apparatus.

In this case, when a case where the blocking film 322 is transparent and the two-dimensional is displayed is compared with a case where the blocking film 322 is opaque and the three-dimensional image is displayed, the luminance of the display apparatuses in each case may be similar.

Therefore, with the structure shown in FIG. 13, it is possible to effectively increase the resolution of the three-dimensional image by increasing the luminance of the three-dimensional image.

A display apparatus according to one embodiment may include a panel, a light source unit provided on the panel and for displaying an image, and an image conversion unit disposed in front of the light source unit and for converting the image displayed from the light source unit into a two-dimensional image or a three-dimensional image, in which the light source unit may have a light emitting group in which a plurality of light emitting pixels are provided to be disposed to be spaced apart from each other on the panel, and a plurality of light emitting groups may be provided to be disposed to be spaced apart from each other on the panel.

A separation distance between the plurality of light emitting group may be provided to be greater than a separation distance between the plurality of pixels.

The light emitting group may be provided so that the plurality of pixels are disposed to be spaced from each other on the panel in a plan view.

The plurality of light emitting groups may be disposed to be spaced apart from each other in a first direction and disposed to be spaced apart from each other in a second direction orthogonal to the first direction.

In any one light emitting group, some of the plurality of pixels may display an image viewed by a user's left eye, and the remaining pixels of the plurality of pixels may display an image viewed by the user's right eye.

The light source unit may include a first array in which the plurality of light emitting groups are arranged linearly, and a second array which is disposed to be spaced apart from the first array and in which the plurality of light emitting groups are arranged linearly, any one of the first array and the second array may display the image viewed by the user's left-eye, and the other may display an image viewed by the user's right eye.

The pixel may be provided as a micro-LED.

The image conversion unit may be provided as any one of a lens unit in which a refractive index of light is adjusted according to a control signal and a barrier covering some of the plurality of pixels according to the control signal.

The lens unit may include a body, and a convex lens protruding from the body, provided as a plurality of lens, and arranged in the first direction, and at least some of the convex lenses may be provided to have the same width in a longitudinal direction.

The convex lens may be disposed to have a longitudinal direction orthogonal to the first direction.

At least some of the convex lenses may be disposed to have a longitudinal direction inclined with respect to the first direction.

The barrier may include a support disposed in front of the light source unit and made of a transparent material, and a blocking film disposed in front of the support and changed to be transparent or opaque according to the control signal, and a plurality of blocking films may be provided to be arranged to be spaced apart from each other in the first direction.

The blocking film may be disposed to have a longitudinal direction orthogonal to the first direction.

The blocking film may be disposed to have a longitudinal direction inclined with respect to the first direction.

A display apparatus according to another embodiment may include a panel, a light source unit provided on the panel and for displaying an image, and an image conversion unit disposed in front of the light source unit and for converting the image displayed from the light source unit into a two-dimensional image or a three-dimensional image, in which the image conversion unit may be provided as any one of a lens unit in which a refractive index of light is adjusted according to a control signal and a barrier covering some of a plurality of pixels according to the control signal, the light source unit may have a light emitting group in which a plurality of light emitting pixels are provided to be disposed to be spaced apart from each other on the panel, and a plurality of light emitting groups may be provided to be disposed to be spaced apart from each other on the panel.

The light emitting group may include a first array in which the plurality of pixels are arranged linearly, and a second array which is disposed to be spaced apart from the first array and in which the plurality of pixels are arranged linearly, any one of the first array and the second array may display an image viewed by a user's left-eye, and the other may display an image viewed by the user's right eye.

In the display apparatus according to the present disclosure, the light source unit configured to display an image may be as a plurality of light emitting groups disposed to be spaced apart from each other. The light emitting group may include a plurality of pixels.

Since the light emitting groups spaced apart from each other display different images and are quite away from each other, compared to other display apparatuses in which a plurality of pixels are consecutively disposed to display an image, it is possible to significantly reduce the occurrence of crosstalk between separated light groups displaying different images. Therefore, it is possible to increase the resolution of the three-dimensional image.

In addition, in the display apparatus according to the present disclosure, by manufacturing the pixel forming the light emitting group of the light source unit with micro-LEDs, it is possible to greatly increase the luminance of the display apparatus. Therefore, even when the light emitting groups are consecutively disposed on the panel without any separation distance, the light source unit can have sufficient luminance.

In addition, when the light source conversion unit operates, the light source conversion unit may cover some images or reduce the luminance of the image, and an image having sufficient luminance may be displayed by forming the light source unit as the micro-LED. Therefore, it is possible to increase the resolution of the image to be displayed by increasing the luminance of the image.

Specific effects together with the above-described effects are described together with a description of the following detailed matters for carrying out the invention.

Although the present disclosure has been described above with reference to exemplary drawings, the present disclosure is not limited by the embodiments and drawings disclosed in the specification, and it is apparent that various modifications can be made by those skilled in the art within the scope of the technical spirit of the present disclosure. In addition, even when the operational effects according to the configuration of the present disclosure have not been explicitly described in the description of the embodiments of the present disclosure, it goes without saying that the effects predictable by the corresponding configuration should be recognized.

What is claimed is:

1. A display apparatus comprising:
a panel;
a light source unit on the panel, the light source unit configured to display an image; and
an image conversion unit in front of the light source unit, the image conversion unit configured to convert the image displayed from the light source unit into a two-dimensional image or a three-dimensional image,
wherein the light source unit has a light emitting group in which a plurality of light emitting pixels are spaced apart from each other on the panel, and a plurality of light emitting groups are spaced apart from each other on the panel.

2. The display apparatus of claim 1, wherein a separation distance between the plurality of light emitting groups is greater than a separation distance between the plurality of light emitting pixels.

3. The display apparatus of claim 1, wherein the plurality of light emitting pixels are spaced from each other on the panel in a plan view of the display apparatus.

4. The display apparatus of claim 3, wherein the plurality of light emitting groups are spaced apart from each other in a first direction and spaced apart from each other in a second direction that is orthogonal to the first direction.

5. The display apparatus of claim 1, wherein in any one light emitting group from the plurality of light emitting groups, some of the plurality of light emitting pixels display a left image viewed by a user's left eye, and remaining pixels of the plurality of light emitting pixels display a right image viewed by the user's right eye.

6. The display apparatus of claim 5, wherein the light source unit includes:
a first array in which the plurality of light emitting groups are arranged linearly; and
a second array that is spaced apart from the first array and in which the plurality of light emitting groups are arranged linearly, and
any one of the first array and the second array displays the left image viewed by a user's left eye, and the other displays the right image viewed by the user's right eye.

7. The display apparatus of claim 1, wherein at least one of the plurality of light emitting pixels is a micro-LED.

8. The display apparatus of claim 1, wherein the image conversion unit is any one of a lens unit in which a refractive index of light is adjusted according to a control signal and a barrier covering some of the plurality of light emitting pixels according to the control signal.

9. The display apparatus of claim 8, wherein the lens unit includes:
a body; and
a convex lens protruding from the body, the convex lens including a plurality of lenses arranged in a first direction, and
at least some of the plurality of lenses have a same width in a longitudinal direction.

10. The display apparatus of claim 9, wherein the convex lens has a longitudinal direction orthogonal to the first direction.

11. The display apparatus of claim 9, wherein at least some of the plurality of lenses have a longitudinal direction inclined with respect to the first direction.

12. The display apparatus of claim 8, wherein the barrier includes:
a support in front of the light source unit, the support made of a transparent material; and
a blocking film in front of the support, the blocking film configured to change between being transparent or opaque according to a control signal, and
a plurality of blocking films that are spaced apart from each other in a first direction.

13. The display apparatus of claim 12, wherein the blocking film has a longitudinal direction orthogonal to the first direction.

14. The display apparatus of claim 12, wherein the blocking film has a longitudinal direction inclined with respect to the first direction.

15. A display apparatus comprising:
a panel;
a light source unit on the panel, the light source unit configured to display an image; and
an image conversion unit in front of the light source unit, the image conversion unit configured to convert the image displayed from the light source unit into a two-dimensional image or a three-dimensional image,
wherein the image conversion unit is any one of a lens unit in which a refractive index of light is adjusted according to a control signal and a barrier covering some of a plurality of light emitting pixels according to the control signal,
wherein the light source unit has a light emitting group in which the plurality of light emitting pixels are spaced apart from each other on the panel, and a plurality of light emitting groups are spaced apart from each other on the panel.

16. The display apparatus of claim 15, wherein the light emitting group includes:
a first array in which the plurality of light emitting pixels are arranged linearly; and
a second array spaced apart from the first array and in which the plurality of light emitting pixels are arranged linearly, and
wherein any one of the first array and the second array displays a left image viewed by a user's left eye, and the other displays a right image viewed by the user's right eye.
